(19) United States
(12) Patent Application Publication
(10) Pub. No.: US 2010/0041240 A1
(43) Pub. Date: Feb. 18, 2010

(54) FOCUS RING, PLASMA PROCESSING APPARATUS AND PLASMA PROCESSING METHOD

(75) Inventors: Hiroshi TSUJIMOTO, Nirasaki City (JP); Toshifumi Nagaiwa, Nirasaki City (JP); Tatsuya Handa, Nirasaki City (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/539,250

(22) Filed: Aug. 11, 2009

Related U.S. Application Data
(60) Provisional application No. 61/103,273, filed on Oct. 7, 2008.

(30) Foreign Application Priority Data
Aug. 13, 2008 (JP) 2008-208364

(51) Int. Cl. H01L 21/30; C23C 16/54; H01L 21/3065

(52) U.S. Cl. 438/758; 118/723 R; 118/723 E; 438/710; 156/345.1; 156/345.43; 257/E21.218; 257/E21.211

(57) ABSTRACT

A focus ring of a ring shape is disposed to surround a target substrate on a lower electrode on which the target substrate is mounted in a process chamber. The process chamber receives the target substrate and subjects the received target substrate to a plasma process. At the point of time when the focus ring is first used for the plasma process, a distance between a lower side of an edge portion of the target substrate and a portion of the focus ring facing the lower side of the edge portion of the target substrate is set to be equal to or greater than about 0.4 mm.

### FIELD OF THE INVENTION

The present invention relates to a focus ring, a plasma processing apparatus and a plasma processing method.

### BACKGROUND OF THE INVENTION

Conventionally, in the field of manufacture of semiconductor devices, there are known plasma processing apparatuses for plasmarizing a process gas and subjecting a target substrate, e.g., a semiconductor wafer or a glass substrate for LCD, to a specified process, e.g., an etching process or a film forming process.

In the above-mentioned plasma processing apparatuses, for example, plasma processing apparatuses for performing a plasma etching process on a semiconductor wafer, it has been known to provide a focus ring around the semiconductor wafer mounted on a lower electrode to increase uniformity of plasma processing in a plane of the semiconductor wafer (for example, see Japanese Patent Application Publication Nos. 2008-078208 and 2003-229408 and U.S. Patent Application Publication Nos. 2008/66868A1 and 2005/5859A).

In the plasma processing apparatuses using the focus ring as above, the focus ring itself is etched and exhausted since the focus ring is exposed to plasma. Since process uniformity in the plane of the semiconductor wafer is deteriorated with such exhaustion of the focus ring, there is a need to replace the exhausted focus ring with a new one at the time when the focus ring is exhausted to some extents.

However, such replacement of the focus ring causes deterioration of operation rate of the plasma processing apparatus and increases of running costs. Accordingly, there is a need of increasing the service life of the focus ring for improvement of operation rate of the plasma processing apparatus and reduction of running costs.

### SUMMARY OF THE INVENTION

In view of the above, the present invention provides a focus ring, a plasma processing apparatus and a plasma processing method, wherein the service life of the focus ring is increased to thereby improve operation rate of the plasma processing apparatus and reduce running costs compared to a conventional one.

In accordance with a first aspect of the invention, there is provided a focus ring of a ring shape, which is disposed to surround a target substrate on a lower electrode on which the target substrate is mounted, in a process chamber for receiving the target substrate and subjecting the received target substrate to a plasma process, wherein, at the point of time when the focus ring is first used for the plasma process, a distance between a lower side of an edge portion of the target substrate and a portion of the focus ring facing the lower side of the edge portion of the target substrate is set to be equal to or greater than about 0.4 mm.

In accordance with a second aspect of the invention, there is provided a plasma processing apparatus including: a process chamber for receiving a target substrate and subjecting the received target substrate to a predetermined plasma process; a lower electrode provided within the process chamber the target substrate is mounted on the lower electrode; a radio frequency (RF) power supply for supplying RF power to the lower electrode to generate plasma; an upper electrode that is disposed to face the lower electrode; and a focus ring disposed to surround the target substrate on the lower electrode, wherein, at the point of time when the focus ring is first used for the plasma process, a distance between a lower side of an edge portion of the target substrate and a portion of the focus ring facing the lower side of the edge portion of the target substrate is set to be equal to or greater than about 0.4 mm.

In accordance with a third aspect of the invention, there is provided a plasma processing method for subjecting a target substrate to a predetermined plasma process by using a plasma processing apparatus in which the target substrate is mounted on a lower electrode within a process chamber having an upper electrode and the lower electrode being disposed opposite to each other therein, a ring-shaped focus ring is disposed on the lower electrode to surround the target substrate, and RF power is applied to the lower electrode, wherein, the focus ring is set such that, at the point of time when the focus ring is first used for the plasma process, a distance between a lower side of an edge portion of the target substrate and a portion of the focus ring facing the lower side of the edge of the target substrate is equal to or greater than about 0.4 mm.

### BRIEF DESCRIPTION OF THE DRAWINGS

The objects and features of the present invention will become apparent from the following description of embodiments, given in conjunction with the accompanying drawings, in which:

FIG. 1 is a view showing a general configuration of a plasma etching apparatus in accordance with one embodiment of the present invention;

FIG. 2 is a view showing main parts of the plasma etching apparatus and a focus ring shown in FIG. 1;

FIG. 3 is a graph showing a result of examination on a change of etching rate with use time;

FIG. 4 is a graph showing a result of examination on an effect of change of thickness A and B and angle C on etching rate; and

FIG. 5 is a graph showing a result of examination on a relation between variation of etching rate when thickness A is changed by 0.2 mm and thickness A before start of use.

### DETAILED DESCRIPTION OF THE EMBODIMENTS

Hereinafter, a focus ring, a plasma processing apparatus and a plasma processing method in accordance with embodiments of the present invention will be described in detail with reference to the accompanying drawings which form a part hereof.

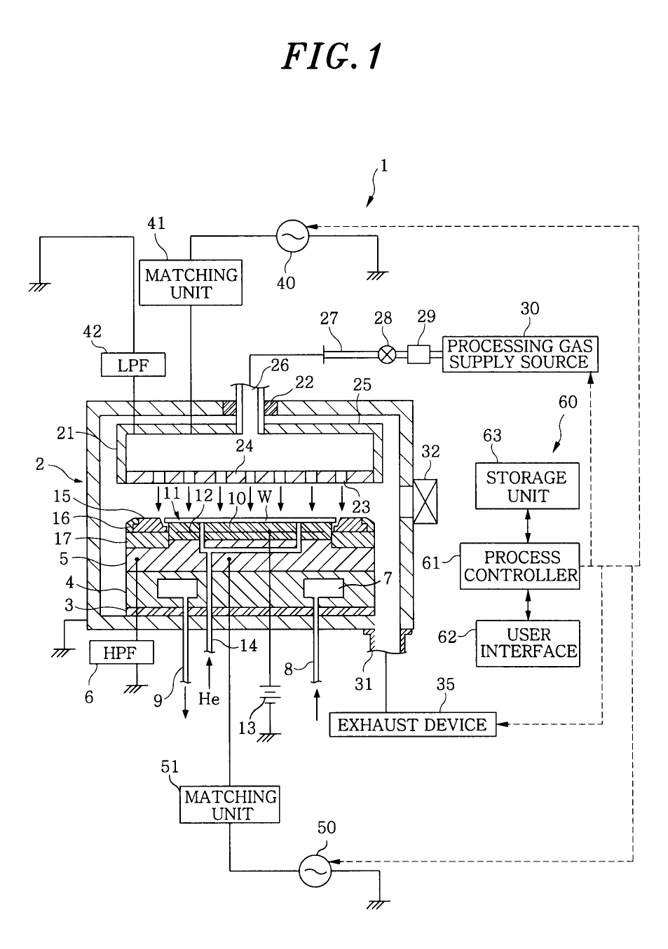

FIG. 1 is a view showing a general configuration of a plasma etching apparatus 1 as a plasma processing apparatus in accordance with one embodiment of the present invention, and FIG. 2 is a view showing main parts of a focus ring 15 and the plasma etching apparatus 1 in accordance with the embodiment of the present invention. First, the general configuration of the plasma etching apparatus 1 will be described with reference to FIG. 1.

The plasma etching apparatus 1 is configured as a capacitively coupled parallel plate type etching apparatus in which an upper and a lower electrode plate are disposed opposite to each other in parallel and power supplies for generation of plasma are connected to the electrode plates, respectively.

The plasma etching apparatus 1 includes a grounded cylindrical process chamber 2 made of aluminum or the like whose surface is anodized, for example. In the bottom of the process chamber 2 is provided a substantially columnar susceptor support 4 for supporting a target substrate, e.g., a semiconductor wafer W, is loaded via an insulating plate 3 made of ceramic or the like. In addition, a susceptor (mounting table) 5 serving as a lower electrode is disposed on the susceptor support 4. A high pass filter (HPF) 6 is connected to the susceptor 5.

A coolant channel 7 is provided within the susceptor support 4. A coolant is introduced through a coolant introduction line 8 in the coolant channel 7 and the coolant is circulated in the coolant channel 7 to be discharged through a coolant discharge line 9. The cold heat of the coolant is transferred to the semiconductor wafer W via the susceptor 5, which causes the semiconductor wafer W to be controlled to a desired temperature.

The susceptor 5 has a protruded upper central portion of a disc shape and an electrostatic chuck 11 having the substantial same shape as the semiconductor wafer W is disposed on the upper central portion. The electrostatic chuck 11 includes an electrode 12 arranged within an insulation material 10. The electrostatic chuck 11 electrostatically attracts the semiconductor wafer W by, for example, a Coulomb force generated by applying a DC voltage of, e.g., 1.5 kV from a DC power supply 13, which is connected to the electrode 12, to the electrostatic chuck 11.

A gas passage 14 for supplying a heat transfer medium (e.g., He gas or the like) to a back surface of the semiconductor wafer W is formed in the insulating plate 3, the susceptor support 4, the susceptor 5 and the electrostatic chuck 11, and the cold heat of the susceptor 5 is transferred to the semiconductor wafer W through the heat transfer medium so that the semiconductor wafer W is maintained at a desired temperature.

An annular focus ring 15 is disposed on an upper peripheral portion of the susceptor 5 to surround the semiconductor wafer W mounted on the electrostatic chuck 11. The focus ring 15 serves to improve etching uniformity. In this embodiment, the focus ring 15 is made of silicon.

As shown in FIG. 2, an outer member 16 made of quartz is provided outwardly of the focus ring 15, and a bottom member 17 is provided under the focus ring 15. In addition, an inner peripheral portion 15a of the focus ring 15 has a thin thickness and extends below the peripheral edge portion of the semiconductor wafer W. Accordingly, the top side of the inner peripheral portion 15a of the focus ring 15 is arranged to face the lower side of the peripheral edge portion of the semiconductor wafer W. In this embodiment, a distance between the top side of the inner circumference 15a of the focus ring 15 and the lower side of the circumference of the semiconductor wafer W (distance “a” shown in FIG. 2) is configured to be equal to or more than 0.4 mm at the time when the focus ring 15 is first used for plasma processing (at the time when a new focus ring 15 begins to be used) The reason for this will be described later.

The focus ring 15 includes an inclined portion 15c whose thickness is gradually increased outwardly of the inner peripheral portion 15a. In addition, the focus ring 15c further includes a thick flat portion 15b having a flat top side outwardly of the inclined portion 15c, and a stepped portion 15d for locking and fixing the outer member 16 outwardly of the thick flat portion 15b.

As shown in FIG. 1, an upper electrode 21 is disposed above the susceptor 5 parallel to and opposite to the susceptor 5. The upper electrode 21 is supported at the upper portion of the process chamber 2 through an insulating material 22. The upper electrode 21 includes an electrode plate 24 and a conductive electrode holder 25 for holding the electrode plate 24. The electrode plate 24 is made of, e.g., a conductor or a semiconductor and has a plurality of injection holes 23. The electrode plate 24 has a surface opposite to the susceptor 5.

A gas inlet 26 is provided in the center of the electrode support 25 of the upper electrode 21 and a gas supply pipe 27 is connected to the gas inlet 26. In addition, a processing gas supply source 30 is connected to the gas supply pipe 27 via a valve 28 and a mass flow controller 29. An etching gas for plasma etching process is supplied from the processing gas supply source 30.

A gas exhaust pipe 31 is connected to the bottom of the process chamber 2 and a gas exhaust device 35 is connected to the gas exhaust pipe 31. The gas exhaust device 35 has a vacuum pump such as a turbo molecule pump and is configured to exhaust the processing chamber 2 to a predetermined decompressurized atmosphere, for example, a predetermined pressure of about 1 Pa or less. In addition, a gate valve 32 is provided in a side wall of the process chamber 2 and the semiconductor wafer W is transferred between the processing chamber 2 and an adjacent load lock chamber (not shown) with the gate valve 32 opened.

A first radio frequency (RF) power supply 40 is connected to the upper electrode 21 and a matching unit 41 is provided on a power feed line extending from the first RF power supply 40 to the upper electrode 21. In addition, a low pass filter (LPF) 42 is connected to the upper electrode 21. The first RF power supply 40 has a frequency ranging from about 50 to about 150 MHz (60 MHz in this embodiment). A high-density plasma in a desirable dissociated state can be generated in the process chamber 2 by applying RF power of such a high frequency to the upper electrode 21.

A second radio frequency (RF) power supply 50 is connected to the susceptor 5 as a lower electrode and a matching unit 51 is provided on a power feed line extending from the second RF power supply 50 to the susceptor 5. The second RF power supply 50 has a frequency range lower than that of the first RF power supply 40 and a proper ion action can be applied to the semiconductor wafer W as the target substrate without doing damage to the semiconductor wafer W by applying RF power of such a frequency range to the susceptor 5. That is, the second RF power supply 50 is for applying RF power for bias. A frequency of the second RF power supply 50 is preferably about 1 to about 20 MHz (2 MHz in this embodiment).

Operation of the above-configured plasma etching apparatus 1 is generally controlled by a controller 60. The controller 60 includes a process controller 61 having a CPU and controlling components of the plasma etching apparatus 1, a user interface 62 and a storage unit 63.

The user interface 62 includes a keyboard to allow a process manager to input commands for managing the plasma etching apparatus 1, a display for displaying operation situations of the plasma etching apparatus 1, etc.

The storage unit 63 stores recipes including a control program (software) for controlling various processes performed in the plasma etching apparatus 1 with the process controller 61, process condition data, etc. If necessary, by calling a recipe from the storage unit 63 and causing the process controller 61 to execute the recipe through instructions from the user interface 62, the plasma etching apparatus 1 performs a desired process under the control of the process controller 61. In addition, as the recipes of the control program, the process condition data and the like, ones stored in computer storage media (for example, a hard disk, CD, flexible disk, semiconductor memory, etc.) readable by a computer may be used, or ones transmitted from other devices on-line at any time through, for example, a dedicated line, may be used.

When the above-configured plasma etching apparatus 1 performs plasma etching on the semiconductor wafer W, the semiconductor wafer W is first transferred from the load lock chamber (not shown) into the process chamber 2 with the gate valve 32 opened and then is loaded on the electrostatic chuck 11. Then, by applying a DC voltage from the DC power supply 13 to the electrostatic chuck 11, the semiconductor wafer W is electrostatically attracted on the electrostatic chuck 11. Then, the gate valve 32 is closed and the process chamber 2 is exhausted up to a predetermined degree of vacuum by the gas exhaust device 35.

Thereafter, the valve 28 is opened and a predetermined etching gas is introduced from the processing gas supply source 30 into a hollow portion of the upper electrode 21 through the processing gas supply line 27 and the gas inlet 26, with its flow rate controlled by the mass flow controller 29, and is uniformly injected toward the semiconductor wafer W through the injection holes 23 of the electrode plate 24, as indicated by arrows in FIG. 1.

Then, the interior of the process chamber 2 is maintained at a predetermined pressure. Thereafter, RF power of a predetermined frequency is applied from the first RF power supply 40 to the upper electrode 21. Accordingly, an RF electric field is produced between the upper electrode 21 and the susceptor 5 as the lower electrode and the etching gas is dissociated and converted into plasma.

In the meantime, RF power of a frequency lower than that of the first RF power supply 40 is applied from the second RF power supply 50 to the susceptor 5 as the lower electrode. Accordingly, ions in plasma are attracted to the susceptor 5 and etching anisotropy is increased by ion-assist.

When a predetermined plasma etching process is ended, the supply of RF power and the supply of processing gas are stopped and the semiconductor wafer W is carried out of the process chamber 2 in an order reverse to the above-described order.

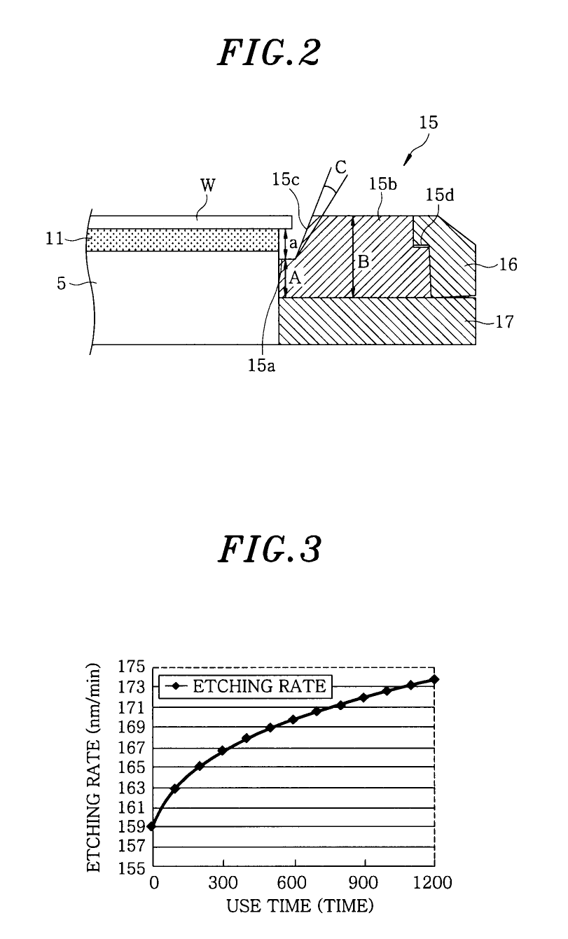

Next, the reason why the focus ring 15 is configured such that the distance “a” shown in FIG. 2 is equal to or more than 0.4 mm in this embodiment will be described. FIG. 3 shows a result of examination on variation in etching rate (average etching rate of a silicon oxide film formed on the semiconductor wafer W) of the semiconductor wafer W in relation to use time during which a new focus ring 15 is used. As shown in FIG. 3, the variation of etching rate is great until the use time reaches 300 hours or so after the focus ring 15 begins to be used.

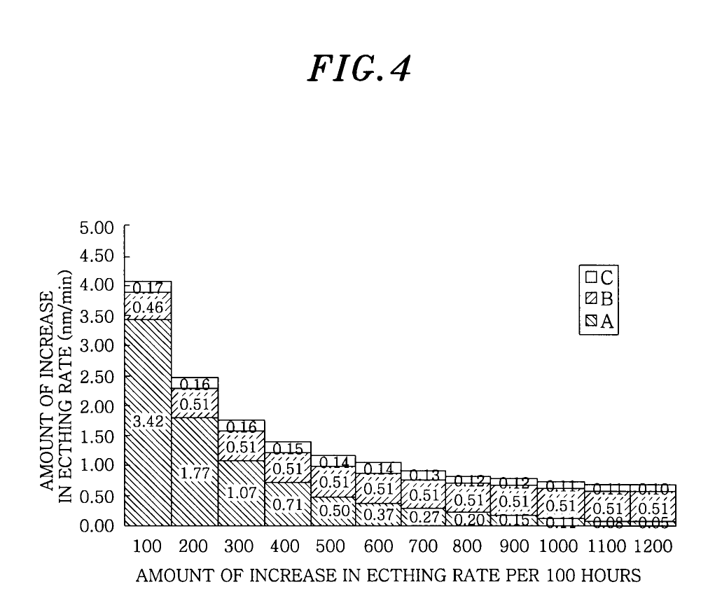

While the focus ring 15 is used, the focus ring 15 is exhausted by plasma action. At this time, thickness A of the inner peripheral portion 15a, thickness B of the flat portion 15b and angle C of the inclined portion 15c, as shown in FIG. 2, are changed. FIG. 4 shows a result of examination on an effect of change of the thickness A and B and the angle C on etching rate. More specifically, FIG. 4 shows a result of examination on an effect of change of the thickness A (initial value: 3 mm) and B (initial value: 8.3 mm) and the angle C (initial value: 75°) on etching rate (amount of increase in etching rate) every 100 hours during which the new focus ring 15 is used, showing the amount of increase in etching rate by A, B and C in turn from the bottom of each bar graph.

As shown in FIG. 4, it is the thickness A that has the greatest effect on change of etching rate immediately after the focus ring 15 begins to be used. In particular, the variation of etching rate is great until the use time reaches 300 hours or so after the focus ring 15 begins to be used.

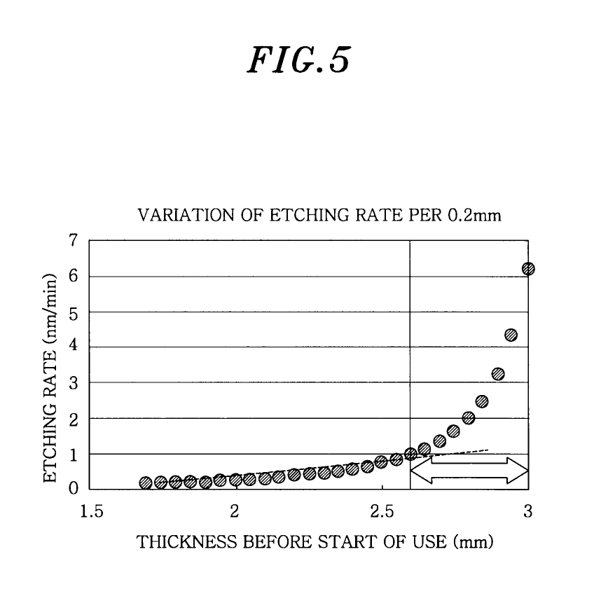

A graph of FIG. 5 shows a result of examination on a relationship between variation (longitudinal axis) of etching rate (nm/min) when the thickness A is changed by 0.2 mm and the thickness A (mm) (horizontal axis) before the focus ring 15 is used. As shown in the graph of FIG. 5, 3 mm to 2.9 mm of the thickness A before use of the focus ring 15 gives a great variation of etching rate when the thickness A is changed by 0.2 mm. The variation of etching rate is about 2 nm at about 2.8 mm of the thickness A before use of the focus ring 15, and is about 1 nm at about 2.6 mm of the thickness A. When the thickness A before use of the focus ring 15 becomes smaller than 2.6 mm, the variation of etching rate is little changed.

In this case, the distance “a” between the top side of the inner peripheral portion 15a of the focus ring 15 and the lower side of the peripheral edge portion of the semiconductor wafer W, as shown in FIG. 2, is 0.2 mm for 3 mm of the thickness A before use of the focus ring 15, 0.4 mm for 2.8 mm of the thickness A, and 0.6 mm for 2.6 mm of the thickness A. Accordingly, in this embodiment, at the point of time when the focus ring 15 is initially used for plasma processing (that is, at the point of time when a new focus ring 15 begins to be used), the distance “a” between the top side of the inner peripheral portion 15a of the focus ring 15 and the lower side of the peripheral edge portion of the semiconductor wafer W is set to equal to or greater than 0.4 mm, thereby restraining the variation of etching rate due to exhaustion of the focus ring 15.

Since this allows little change of etching rate even when the focus ring 15 is exhausted, the focus ring 15 is allowed to be used for a longer time, which results in extended service life of the focus ring 15, improvement of operation rate and reduction of running costs of the plasma processing apparatus 1 over conventional techniques. In addition, as shown in FIG. 5, since the variation of etching rate remains little changed even when the distance “a” is set to be greater than 0.6 mm, the distance “a” is preferably set to be equal to or greater than 0.4 mm and equal to or smaller than 0.6 mm.

The reason which a variation in the distance “a” between the top side of the inner peripheral portion 15a of the focus ring 15 and the lower side of the peripheral edge portion of the semiconductor wafer W has a great effect on the variation of etching rate is supposed as follows.

That is, since the focus ring 15 made of silicon is disposed on the susceptor (lower electrode) 5 to which RF power is applied although the bottom member 17 made of quartz is disposed therebetween, it is considered that a path of RF power from the susceptor (lower electrode) 5 through the focus ring 15 is formed and a capacitor is formed between the top side of the inner peripheral portion 15a of the focus ring 15 and the lower side of the peripheral edge portion of the semiconductor wafer W. In addition, since the capacitance of this capacitor is in inverse proportion to the distance “a”, the capacitance becomes large as the distance “a” becomes small, and variation of the capacitance due to change of the distance a becomes large. Accordingly, it is considered that the etching rate of the semiconductor wafer W becomes low as the distance “a” becomes small and variation of the etching rate due to change of the distance “a” becomes large.

On the other hand, since the capacitance of the capacitor becomes small as the distance “a” becomes large to some extents, it is considered that a flow of RF power through the focus ring 15 becomes small while RF power directly flowing from the susceptor (lower electrode) 5 to the semiconductor wafer W increases, thereby increasing the etching rate. In addition, even when the distance “a” is changed, it is considered that variation of the etching rate becomes small since variation of the capacitance of the capacitor is small.

According to the embodiment of the present invention, there are provided a focus ring, a plasma processing apparatus and a plasma processing method, wherein the service life of the focus ring is increased to thereby improve operation rate of the plasma processing apparatus and reduce of running costs compared to a conventional one.

The present invention is not limited to the above embodiments but it is to be understood that the embodiments may be modified in various ways. For example, although it has been illustrated in the above embodiments that the present invention is applied to the plasma etching apparatus of a type of applying two kinds of RF power to the upper electrode and the lower electrode, respectively, the present invention may be equally applied to, for example, a plasma etching apparatus of a type of applying only one kind of RF power to the lower electrode, a plasma etching apparatus of a type of applying two kinds of RF power to the lower electrode, etc.

While the invention has been shown and described with respect to the embodiments, it will be understood by those skilled in the art that various changes and modification may be made without departing from the scope of the invention as defined in the following claims.

What is claimed is:

1. A focus ring of a ring shape, which is disposed to surround a target substrate on a lower electrode on which the target substrate is mounted, in a process chamber for receiving the target substrate and subjecting the received target substrate to a plasma process,
wherein, at the point of time when the focus ring is first used for the plasma process, a distance between a lower side of an edge portion of the target substrate and a portion of the focus ring facing the lower side of the edge portion of the target substrate is set to be equal to or greater than about 0.4 mm.

2. The focus ring of claim 1, wherein, at the point of time when the focus ring is first used for the plasma process, the distance between the lower side of the edge portion of the target substrate and the portion of the focus ring facing the lower side of the edge portion of the target substrate is set to be equal to or smaller than about 0.6 mm.

3. The focus ring of claim 1, wherein the focus ring is made of silicon.

4. A plasma processing apparatus comprising:
a process chamber for receiving a target substrate and subjecting the received target substrate to a predetermined plasma process;
a lower electrode provided within the process chamber the target substrate is mounted on the lower electrode;
a radio frequency (RF) power supply for supplying RF power to the lower electrode to generate plasma;
an upper electrode disposed to face the lower electrode; and
a focus ring disposed to surround the target substrate on the lower electrode, wherein, at the point of time when the focus ring is first used for the plasma process, a distance between a lower side of an edge portion of the target substrate and a portion of the focus ring facing the lower side of the edge portion of the target substrate is set to be equal to or greater than about 0.4 mm.

5. The plasma processing apparatus of claim 4, wherein, at the point of time when the focus ring is first used for the plasma process, the distance between the lower side of the edge portion of the target substrate and the portion of the focus ring facing the lower side of the edge portion of the target substrate is set to be equal to or smaller than about 0.6 mm.

6. The plasma processing apparatus of claim 4, wherein the focus ring is made of silicon.

7. The plasma processing apparatus of claim 6, wherein the focus ring is disposed on the lower electrode via a member made of quartz.

8. A plasma processing method for subjecting a target substrate to a predetermined plasma process by using a plasma processing apparatus in which the target substrate is mounted on a lower electrode within a process chamber having an upper electrode and the lower electrode being disposed opposite to each other therein, a ring-shaped focus ring is disposed on the lower electrode to surround the target substrate, and RF power is applied to the lower electrode,
wherein, the focus ring is set such that, at the point of time when the focus ring is first used for the plasma process, a distance between a lower side of an edge portion of the target substrate and a portion of the focus ring facing the lower side of the edge of the target substrate is equal to or greater than about 0.4 mm.

9. The plasma processing method of claim 8, wherein, the focus ring is set such that, at the point of time when the focus ring is first used for the plasma process, the distance between the lower side of the edge portion of the target substrate and the portion of the focus ring facing the lower side of the edge portion of the target substrate is equal to or smaller than about 0.6 mm.

10. The plasma processing method of claim 8, wherein the focus ring is made of silicon.

11. The plasma processing method of claim 10, wherein the focus ring is disposed on the lower electrode via a member made of quartz.
